(19) United States
(12) Patent Application Publication
(10) Pub. No.: US 2006/0124280 A1
(43) Pub. Date: Jun. 15, 2006

(54) Flat plate heat transferring apparatus and manufacturing method thereof

(76) Inventors: Young-Duck Lee, Seoul (KR); Young-Ho Hong, Gyeonggi-do (KR); Ku-Young Kim, Gyeonggi-do (KR); Hyun-Tae Kim, Seoul (KR)

Correspondence Address: JONES DAY, 222 EAST 41ST ST, NEW YORK, NY, 10017, US

(21) Appl. No.: 10/522,458

(22) PCT Filed: Feb. 19, 2003
(86) PCT No.: PCT/KR03/00335

§ 371 Date: Nov. 11, 2005

(30) Foreign Application Priority Data
Oct. 16, 2002 (KR) 10-2002-0063327

(51) Int. Cl. H05K 7/20; F28D 15/00

(52) U.S. Cl. 165/104.26; 165/104.33; 361/700

(57) ABSTRACT

Disclosed is a flat plate heat transfer device which includes a flat plate case installed between a heat source and a heat dissipating unit and receiving a working fluid evaporated with absorbing heat at the heat source and condensed with dissipating heat at the heat dissipating unit, and at least one layer of mesh installed in the case and formed so that wires are alternatively woven each other horizontally and vertically in turns. A steam passage through which the working fluid may flow is formed along the surface of the wires from the junctions of the mesh.

### TECHNICAL FIELD

The present invention relates to a flat plate heat transferring apparatus adopted in electronic equipment, and more particularly to a flat plate heat transfer device for ensuring reliability of a product and improving a heat transferring performance by preventing distortion of a case of a cooling device with ensuring a vapor channel.

### BACKGROUND ART

Recently, along with the development of the high integration technique, electronic equipment such as a notebook computer or a PDA become smaller and thinner. In addition, in order to cope with the increased needs for improving the higher responsiveness of the electronic equipment, power consumption of the electronic equipment tends to increase gradually. The increased power consumption also causes the electronic components in the equipment to generate a large amount of heat during the operation of electronic equipment. Thus, there are used various types of flat plate heat transfer device in the electronic equipment so as to dissipate the heat outside.

As an example of the cooling device for cooling the electronic components, a heat pipe is widely known. The heat pipe is constructed to seal a container in order to isolate an inside of the container from the atmosphere after decompressing the inside of the sealed container into a vacuum and then charging a working fluid therein. As for the operation, the working fluid is heated and evaporated near a heat source at which the heat pipe is installed, and then flows into a cooling unit. The vapor is again condensed into a liquid state in the cooling unit, and then returns to its original position. Thus, the heat generated in the heat source is dissipated outside owing to such a circulation structure, and the device may be cooled.

U.S. Pat. No. 5,642,775 issued to Akachi discloses a flat plate heat pipe structure having a film plate having fine channels called as capillary tunnels and filled with working fluid therein. When one end of the plate is heated, the working fluid heats up and evaporates into vapor, and then moves into a cooling unit at the other end of each passage. The working fluid is then cooled again and condensed, and then moved to a heating unit. The flat plate heat pipe of Akachi may be applied between a motherboard and printed circuit board. However, in its manufacture aspect, forming such small and dense capillary tunnels using extrusion is very difficult.

U.S. Pat. No. 5,306,986 issued to Itoh discloses an air-sealed lengthwise container and a heat carrier (working fluid) filled in the container. In the above patent, a tilted groove is formed on the inner side of the container and the container has sharp corners so that the condensed working fluid may be evenly distributed over the entire area of the container in order to absorb and dissipate heat effectively.

U.S. Pat. No. 6,148,906 issued to Li et al. discloses a flat plate heat pipe for transferring heat from a heat source positioned in a main body of electronic equipment to a heat sink positioned outside. This heat pipe is composed of a bottom plate having depressions for receiving a plurality of rods, and an upper plate for covering the bottom plate. The space among the bottom plate, the upper plate and the rods is decompressed and filled with working fluid. As mentioned above, the working fluid in the channel absorbs heat from a heating unit and moves to a cooling unit in a vapor state, and the working fluid then dissipates heat in the cooling unit and is condensed. Through this circulating operation, the working fluid cools the device.

FIG. 1 shows a heat diffuser installed between a heat source 100 and a heat sink 200, as another example of the conventional cooling device. The heat diffuser is configured so that a working fluid is filled in a sealed metal case 1 having a small thickness. A wick structure 2 is formed on the inner side of the metal case 1. The heat generated at the heat source 100 is transferred to a part of the wick structure 2 on the heat diffuser in contact with the heat source. In this region, the working fluid possessed in the wick structure 2 evaporates and diffuses to all directions through an inner space 3 of the metal case 1. This working fluid is condensed after the heat is dissipated through the wick structure 2 at a cooling region near the heat sink 200. The heat dissipated in the above condensing process is transferred to the heat sink 200, and then dissipated outside by means of the forced convection heating method using a cooling fan 300.

The above-mentioned cooling devices should have a space where the vapor may flow since the working fluid in a liquid state may absorb heat from the heat source and evaporate, and the evaporated vapor may move again to the cooling area. However, making a vapor passage in the flat plate heat transfer device having a small thickness is not easy. In particular, since the case of the flat plate heat transfer device keeps its inside at vacuum, the upper and lower plates may be distorted or crushed in the manufacturing procedure, thereby causing the deterioration of product reliability.

The inventors of the present invention thus looked for a way to give a vapor passage which may ensure smooth flow of the evaporated working fluid in addition to preventing distortion of the case plates in the flat plate heat transfer device whose thickness is gradually reduced.

### DISCLOSURE OF INVENTION

Therefore, the present invention is designed to solve the problems of the prior art, and it is an object of the present invention to provide a flat plate heat transfer device which may give a space where an evaporated working fluid may flow smoothly in a case of a cooling device, and also which is interposed between upper and lower plates for supporting them in order to ensure the reliability of products by preventing distortion or crush of the upper and lower plates.

In order to accomplish the above object, the present invention provides a flat plate heat transfer device, which includes a thermally-conductive flat plate case installed between a heat source and a heat dissipating unit for receiving a working fluid which evaporates after absorbing heat from the heat source and condenses after dissipating heat at the heat dissipating unit; and at least one layer of mesh installed in the case and having wires woven alternatively, wherein a vapor passage is formed along the surface of the wires from the junctions of the mesh so that the evaporated working fluid can flow therein.

Preferably, an opening spacing of the mesh [M=(1−Nd)/N] ranges between 0.19 mm and 2.0 mm, where N is the mesh number, and d is a diameter of the wire (inch), and a diameter of the mesh wire ranges between 0.17 mm and 0.5 mm.

In addition, an opening area of the mesh preferably ranges between 0.036 mm² and 4.0 mm².

Preferably, the mesh number is not more than 60 on the basis of ASTM specification E-11-95.

In another aspect of the present invention, the mesh includes at least one layer of sparse mesh for providing a vapor passage for the evaporated working fluid; and at least one layer of dense mesh having the mesh number relatively greater than the sparse mesh and providing a liquid passage for the liquid working fluid.

Preferably, an opening spacing of the dense mesh [M=(1−Nd)/N] ranges between 0.019 mm and 0.18 mm, where N is the mesh number, and d is a diameter of the wire (inch), and a diameter of the dense mesh wire ranges between 0.02 mm and 0.16 mm.

Preferably, an opening area of the dense mesh ranges between 0.00036 mm² and 0.0324 mm².

In addition, the number of the dense mesh is preferably not more than 80 on the basis of ASTM specification E-11-95.

Preferably, the dense mesh is arranged near the heat source, while the sparse mesh positioned upon the dense mesh is arranged near the heat dissipating unit.

According to still another aspect of the present invention, the sparse mesh may be interposed between the dense mesh layers.

According to further another aspect of the present invention, at least one layer of additional dense mesh for connecting the dense meshes to at least a part of the sparse mesh may be further provided between the dense meshes in order to a liquid passage for a working fluid.

According to still further another aspect of the present invention, at least one layer of middle mesh having the mesh number relatively greater than the sparse mesh and relatively smaller than the dense mesh may be further included.

Preferably, the sparse mesh is interposed between the dense mesh and the middle mesh.

More preferably, at least one layer of additional dense mesh for connecting the dense mesh layer and the middle mesh layer to at least a part of the sparse mesh may be further provided between the dense mesh and the middle mesh in order to provide a passage.

As an alternative, at least one layer of additional middle mesh for connecting the dense mesh layer and the middle mesh layer to at least a part of the sparse mesh may be further provided between the dense mesh and the middle mesh in order to provide a passage.

According to a preferred embodiment of the present invention, there is also provided a flat plate heat transfer device wherein the dense mesh is arranged near the heat source so that the working fluid is evaporated into a vapor by the heat absorbed from the heat source, wherein the sparse mesh is arranged in contact with the dense mesh in order to provide a vapor passage through which the evaporated working fluid flows, and wherein the middle mesh is arranged near the heat dissipating unit and in contact with the sparse mesh in order to emit heat to the heat dissipating unit so that the vapor is condensed.

According to another embodiment of the present invention, the middle mesh may have a vapor flowing space so that the vapor from the sparse mesh flows therein.

A flat plate heat transfer device according to still another embodiment of the present invention may further include a wick structure installed in the flat plat case in contact with the mesh, wherein the wick structure has protrusions on a surface thereof so that the working fluid flows in the wick structure and the working fluid is evaporated using the heat absorbed from the heat source and then transferred to the mesh.

Preferably, the flat plate case may be made using an electrolytic copper film so that a coarse surface becomes an inner side of the case.

In addition, the mesh is preferably made of one selected from the group consisting of metal, polymer and plastic. Here, the metal is selected from the group consisting of copper, aluminum, stainless steel and molybdenum or their alloys.

In addition, the flat plate case in a preferred embodiment of the present invention is made of one selected from the group consisting of metal, polymer and plastic, and the metal is selected from the group consisting of copper, aluminum, stainless steel and molybdenum or their alloys.

According to another aspect of the present invention, there is provided a method for making a flat plate heat transfer device, which includes the steps of: forming upper and lower plates of a thermally-conductive flat plate case respectively; inserting at least one layer of mesh into the case, the mesh having alternatively-woven wire in order to form a vapor passage through which an evaporated vapor is capable of flowing along a surface of the wires from a junction of the mesh; making a case by uniting the upper and lower plates; charging the working fluid into the united case at a vacuum state; and sealing the case to which the working fluid is charged.

According to still another aspect of the present invention, there is also provided a method for making a flat plate heat transfer device, which includes the steps of: forming upper and lower plates of a thermally-conductive flat plate case respectively; inserting at least one layer of sparse mesh and at least one layer of dense mesh in the case, the sparse mesh having alternatively-woven wire and forming a vapor passage through which an evaporated working fluid is capable of flowing along a surface of the wires to a junction of the mesh, the dense mesh having the mesh number relatively greater than the sparse mesh and providing a liquid passage for the working fluid; making a case by uniting the upper and lower plates; charging the working fluid into the united case at a vacuum state; and sealing the case to which the working fluid is charged.

Preferably, the upper and lower plates are united using one selected from the group consisting of brazing, TIG welding, soldering, laser welding, electron beam welding, friction welding, bonding and ultrasonic welding.

### BRIEF DESCRIPTION OF THE DRAWINGS

These and other features, aspects, and advantages of preferred embodiments of the present invention will be more fully described in the following detailed description, taken accompanying drawings. In the drawings:

FIG. 1 is a sectional view showing an example of a flat plate heat transfer device according to the prior art;

FIG. 2 is a sectional view showing a flat plate heat transfer device according to a preferred embodiment of the present invention;

FIG. 3 is a sectional view showing a flat plate heat transfer device according to another embodiment of the present invention;

FIG. 4 is a sectional view showing a flat plate heat transfer device according to still another embodiment of the present invention;

FIG. 5 is a plane view showing a structure of a sparse mesh adopted according to a preferred embodiment of the present invention;

FIG. 6 is a plane view showing a structure of a dense mesh adopted according to a preferred embodiment of the present invention;

FIG. 7 is a plane view showing a part of the mesh adopted according to a preferred embodiment of the present invention in detail;

FIG. 8 is a side sectional view showing a vapor passage formed in the mesh according to a preferred embodiment of the present invention;

FIG. 9 is a side sectional view showing a meniscus formed in the mesh according to a preferred embodiment of the present invention;

FIG. 10 is a plane view showing the mesh similar to FIG. 7 having a meniscus;

FIG. 11 is a sectional view showing a structure of a flat plate heat transfer device according to still another embodiment of the present invention;

FIG. 12 is a sectional view showing a structure of a flat plate heat transfer device according to still another embodiment of the present invention;

FIG. 13 is a sectional view showing a structure of a flat plate heat transfer device according to still another embodiment of the present invention;

FIG. 14 is a sectional view showing a structure of a flat plate heat transfer device according to still another embodiment of the present invention;

FIG. 15 is a sectional view showing a structure of a flat plate heat transfer device according to still another embodiment of the present invention;

FIG. 16 is a sectional view taken along a B-B′ line of FIG. 15; and

FIG. 17 is a sectional view taken along a C-C′ line of FIG. 15.

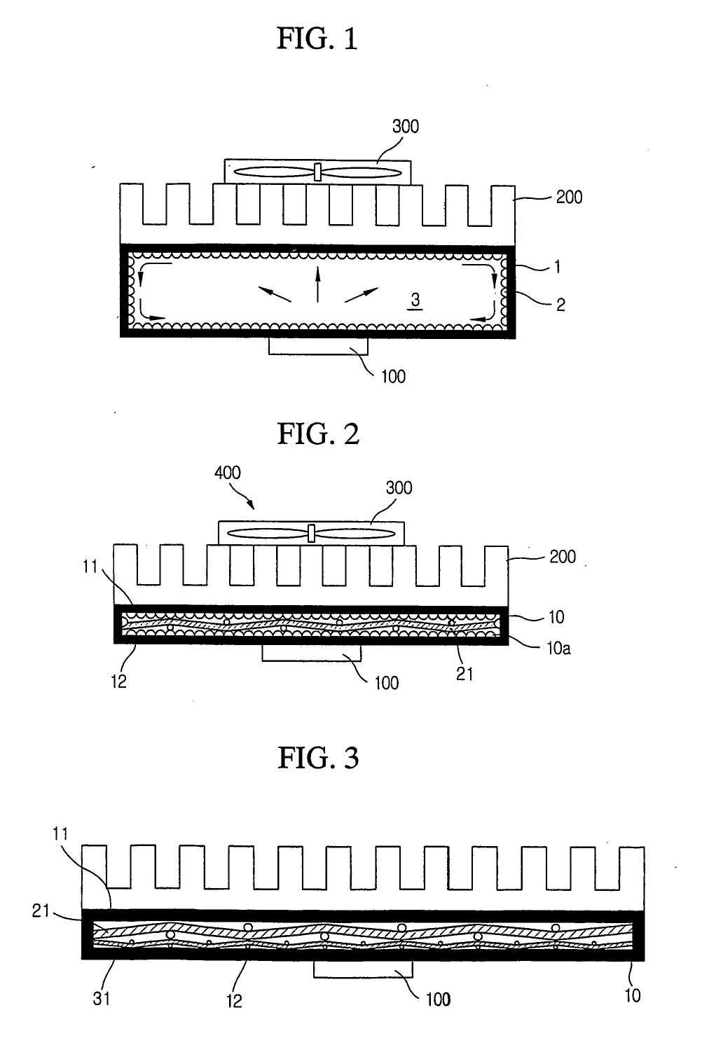

### BEST MODES FOR CARRYING OUT THE INVENTION

Hereinafter, preferred embodiments of the present invention will be described in detail with reference to the accompanying drawings.

FIG. 2 is a sectional view showing a flat plate heat transfer device according to a preferred embodiment of the present invention. Referring to FIG. 2, the flat plate heat transfer device of the present invention includes a flat plate case 10 interposed between a heat source 100 and a heat dissipating unit 400 such as a heat sink, and a mesh 21 contained in the case 10, and a working fluid serving as a medium for transferring heat in the case 10.

The flat plate case 10 is made of metal, conductive polymer or heat conductive plastic having excellent heat conductivity so that it may easily absorb heat from the heat source 100 and emit heat at the heat dissipating unit 400.

According to the present invention, the mesh 21 formed with wires alternately woven is provided between an upper plate 11 and a lower plate 12 of the flat plate case 10. Plane views of the mesh 21 are well shown in FIGS. 5 and 7 in detail.

Referring to FIGS. 5 and 7, the mesh 21 is weaved using horizontal wires 22a and 22b and vertical wires 23a and 23b woven alternatively. This mesh 21 may be made of any of metal, polymer and plastic. Preferably, the metal is one of copper, aluminum, stainless steel, molybdenum or their alloys. In addition, the mesh 21 may be made in various shapes such as a right angle or a square depending on the case shape of the heat transfer device, as described later.

Referring to FIG. 7, an opening spacing (M) of the mesh 21 is generally expressed as follows.
M=(n−Nd)/N Equation 1

Here, d is a diameter (inch) of a metal wire, and N is the mesh number (i.e., the number of mesh lattices existing in one inch).

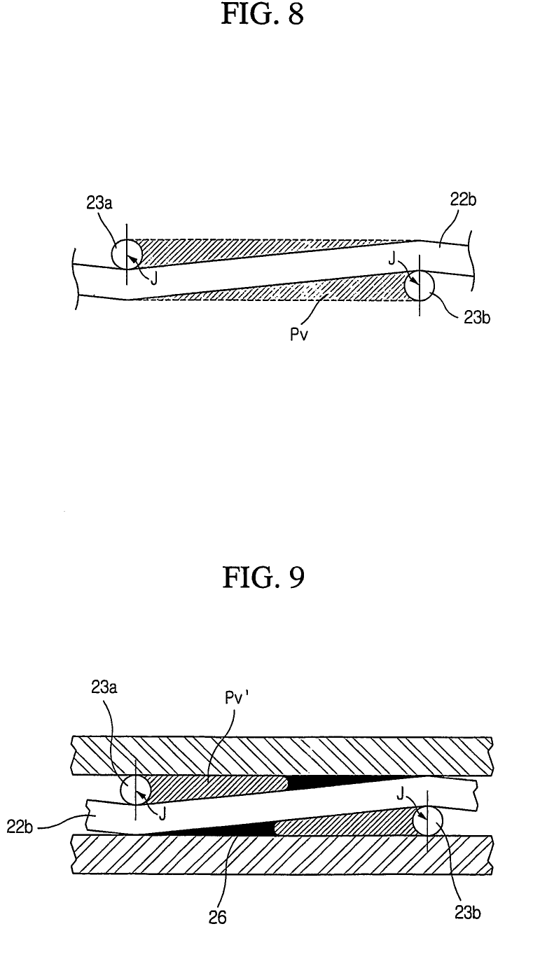

In the present invention, the mesh 21 becomes a means for providing a vapor passage through which a working fluid evaporated by the heat source 100 may flow. Specifically, referring to FIG. 8 partially showing a side view of one sheet of mesh, the mesh 21 is arranged so that the horizontal wire 22b is contacted with a lower surface of the vertical wire 23a and an upper surface of another vertical wire 23b. At this time, there are generated spaces near the upper and lower surfaces of the horizontal wire 22b respectively, and these spaces act as a vapor passage (Pv). The vapor passage (Pv) is formed along each wire surface from junctions (J) at which the horizontal wire 22b is in contact with the vertical wires 23a and 23b. The section of this vapor passage (Pv) is gradually narrowed as it becomes far from the junction (J). Furthermore, as shown in FIG. 7, the vapor passage (Pv) is formed to all direction (i.e., up/down/right/left) from all junctions (J) at which the horizontal wire 22b is contacted with the vertical wires 23a and 23b. Thus, the working fluid vapor may be smoothly diffused through such passages to all direction. A maximum section (A) of this vapor passage (Pv) is calculated using the following equation.
A=(M+d)·d−πd2 Equation 2

As shown in the above equations 1 and 2, the maximum flow path section (A) increases as the mesh number (N) decreases and as the wire diameter (d) increases.

On the other hand, as shown in FIG. 9, a meniscus 26 is formed due to a surface tension of the working fluid in the vapor passage at the junctions (J) of the horizontal wire 22b and the vertical wires 23a and 23b. Thus, a section of an effective vapor passage (Pv′) is decreased rather than the maximum flow path section (A). Here, the ratio of the area of the meniscus 26 to the maximum flow path section (A) decreases as the mesh number (N) decreases and as the wire diameter (d) increases. In case of mounting the mesh in the sealed case and filling with the working fluid in order to realize the heat pipe, if the mesh number (N) is very large and the wire diameter (d) is very small, the maximum flow path section (A) is significantly reduced, thereby increasing flow resistance. Even in a severe case, the vapor passage may be clogged due to surface tension so that the vapor may not flow. According to experiments of the inventors, in case of a mesh conforming to ASTM specification E-11-95, the mesh number (N) is not more than 60, and it may be adopted in this invention. At this time, the flow of the working fluid vapor is not hindered if the wire diameter (d) is over 0.17 mm, since the maximum flow path section (A) is sufficiently large.

According to experiments of the inventors, the diameter (d) of the mesh wire preferably ranges between 0.17 mm and 0.5 mm, the opening spacing (M) of the mesh preferably ranges between 0.19 mm and 2.0 mm, and an opening area of the mesh preferably ranges 0.036 mm² and 4.0 mm².

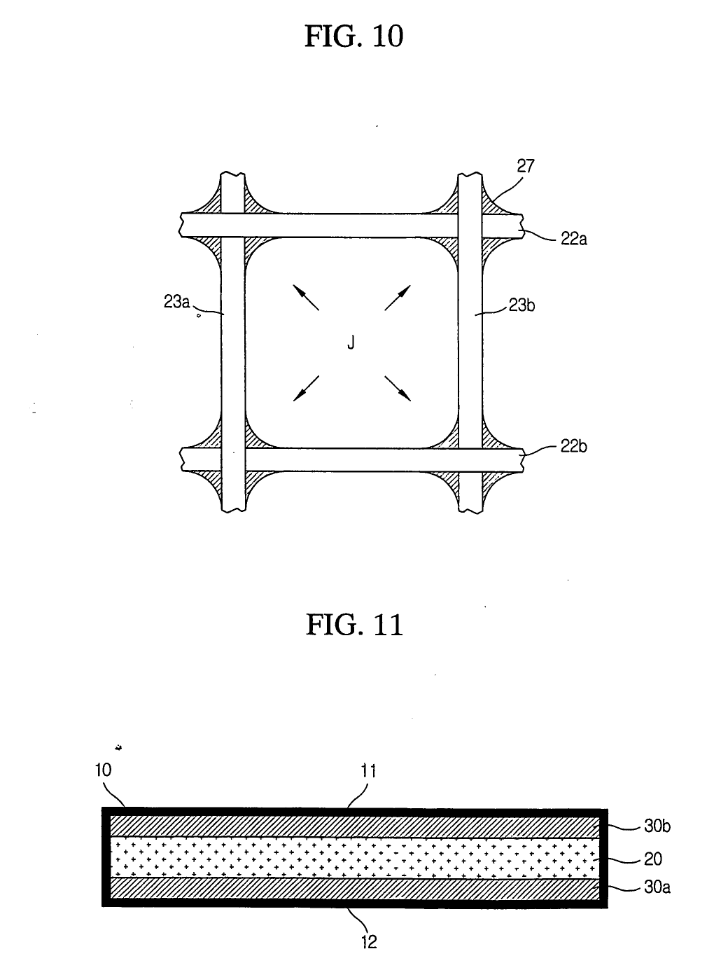

In addition, as shown in FIG. 10, a meniscus 27 is also formed on the plane of the junction (J) at this the horizontal wires 22a and 22b are crossed with the vertical wires 23a and 23b due to the surface tension of the working fluid. This meniscus 27 plays a role of a condenser at which a working fluid vapor transfers heat to outside and is then condensed as well as a liquid passage through which the condensed liquid may flow, as described later.

The flat plate heat transfer device shown in FIG. 2 as a preferred embodiment of the present invention includes single layer of mesh 21 in the flat plate case 10. In this case, a wick structure 10a may be provided in the flat plate case 10 for the purpose of possession, condensation and smooth flow of the working fluid in a liquid state. Preferably, the wick structure 10a is made by sintering copper, stainless steel, aluminum or nickel powder. As another example, the wick structure 10a may also be made by etching polymer, silicon, silica (SiO₂), copper plate, stainless steel, nickel or aluminum plate.

As an alternative, in case the flat plate case of the heat transfer device according to the present invention is made using electrolytic copper foil, its outer surface is smooth but its inner surface is coarse with small protrusions of about 10 μm, which may be used as a wick structure.

In case the wick structure is provided on the inner surface of the case itself, only the mesh layer for giving a vapor passage is needed in the case, thereby decreasing the thickness of the heat transfer device.

Moreover, wick structures having various shapes made by the micromachining disclosed in U.S. Pat. No. 6,056,044 issued to Benson et al. may also be adopted to the case of the present invention.

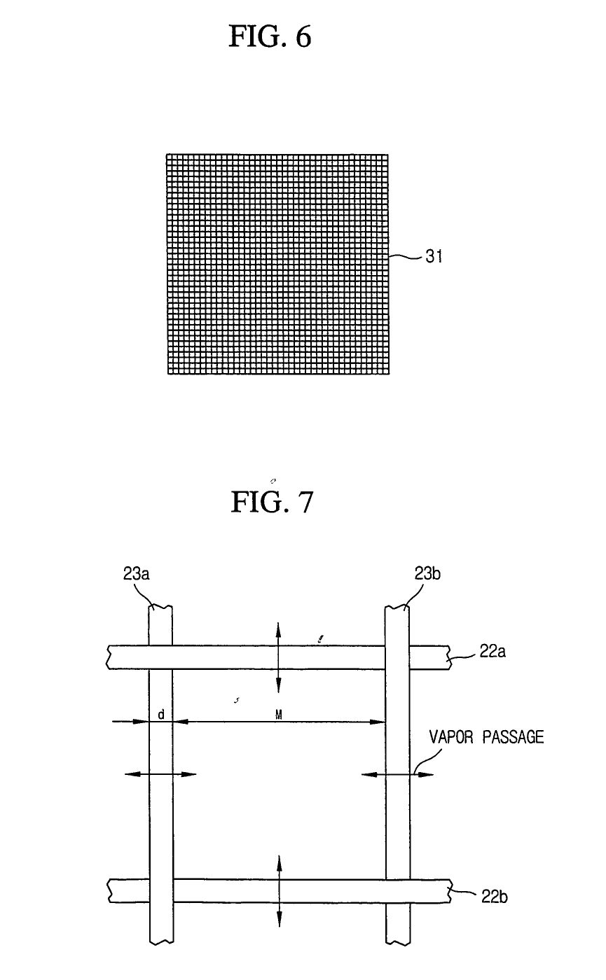

According to a preferred embodiment of the present invention, the liquid passage for ensuring the flow of a condensed liquid may also be realized using a dense mesh. In other words, as shown in FIG. 3, a dense mesh 31 (see a plane view of FIG. 6) may be provided to a lower portion of the mesh 21 acting as a vapor passage at a position near the heat source 100 so that the dense mesh 31 may act as a liquid passage.

The dense mesh 31 has the mesh number (N) relatively greater than the mesh 21 acting as a vapor passage. Preferably, a mesh having the mesh number (N) more than 80 according to ASTM specification E-11-95 is used for the dense mesh 31. According to experiments of the inventors, the dense mesh 31 preferably has a wire diameter (d) in the range between 0.02 mm and 0.16 mm, an opening spacing (M) in the range between 0.019 mm and 0.18 mm, and an opening area in the range between 0.00036 mm² and 0.0324 mm².

Hereinafter, the mesh having a relatively small mesh number (N) and acting as a vapor passage is called a sparse mesh, while a mesh having a relatively great mesh number (N) and acting as a liquid passage is called a dense mesh. As mentioned above, the dense mesh having a relatively great mesh number (N) facilitates the formation of the meniscus so that liquid may easily flow through the mesh. Thus, if the evaporated working fluid emits heat and is then condensed into a liquid, the liquid working fluid may flow through the dense mesh.

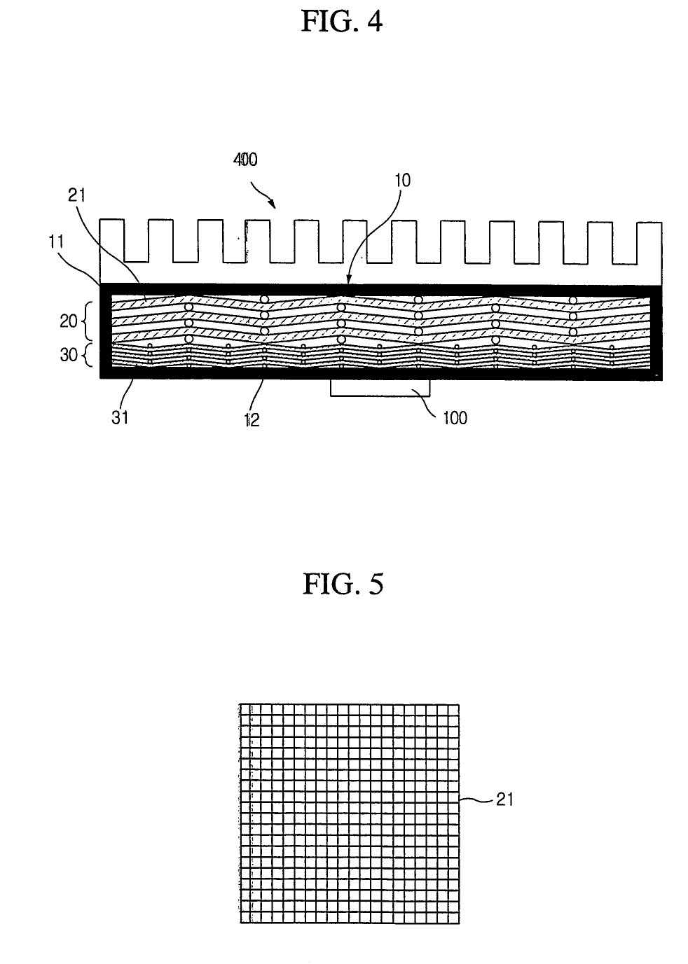

FIG. 4 shows an example of the flat plate heat transfer device which includes a sparse mesh layer 20 in which three sparse meshes 21 are piled up and a dense mesh layer 30 in which three dense meshes 31 are piled up. The number of the meshes is not limited to a special example, but may be suitably selected on consideration of such as the cooling capacity or the thickness of the electronic equipment.

The flat plate heat transfer device described above is preferably made to have a thickness of 0.5˜2.0 mm, but the thickness may also exceed 2.0 mm when required. In addition, the flat plate case 10 (see FIG. 2) is made by connecting the upper plate 11 with the lower plate 12 each other, and the case 10 may have a right angle, a square or other various shapes. The upper and lower plates 11 and 12 may be preferably made using metal, polymer or plastic having a thickness less than 0.5 mm. The metal may include copper, stainless steel, aluminum and molybdenum. In case of polymer, a polymer material having a thermally conductive polymer may be used so that it shows excellent thermal conductivity. In case of plastic, a plastic having excellent thermal conductivity may be adopted. To make the case, one of the above-mentioned materials is cut into a desired shape to make the upper and lower plates 11 and 12, and then the upper and lower plates 11 and 12 are united using various ways such as brazing, TIG welding, soldering, laser welding, electron beam welding, friction welding, bonding and ultrasonic welding. The inside of the united case is decompressed into a vacuum or a low pressure, and then sealed with being filled with a working fluid such as water, ethanol, ammonia, methanol, nitrogen or Freon. Preferably, the amount of the working fluid filled in the case is set in the range of 20˜80% of the inner volume of the case.

Now, an operation of the flat plate heat transfer device according to a preferred embodiment is described with reference to FIG. 3.

As shown in FIG. 3, the lower plate 12 of the heat transfer device according to the present invention is adjacent to the heat source 100, and the heat dissipating unit such as a heat sink or a cooling fan is provided to the upper plate 11. In this state, the heat generated by the heat source 100 is transferred to the dense mesh 31 through the lower plate 12 of the case 10. Then, the working fluid possessed in the dense mesh 31 is heated and evaporated, and the evaporated working fluid is diffused to all directions in the heat transfer device through the vapor passage of the sparse mesh 21.

The diffused vapor is condensed between the junctions (J) of the wires of the sparse mesh 21 and the upper plate 11 of the case 10. The condensation heat generated in the condensing process is transferred to the upper plate 11 of the case, and subsequently dissipated outside by means of the conductive heat transferring, the natural convection, or the compulsory convection heating using a cooling fan.

The condensed working fluid in a liquid state flows to the dense mesh 31 through the junction (J) of the sparse mesh 21 shown in FIG. 10. This liquid working fluid again returns to the evaporator section by means of a capillary force caused by the evaporation at the dense mesh 31 positioned above the heat source 100.

In case of the embodiment shown in FIG. 2, the function of the dense mesh is accomplished by the wick structure formed on the inner side of the flat plate case 10. In other words, the working fluid is evaporated, condensed and flowed in the wick structure.

As understood in the above description, the dense mesh 31 or the dense mesh layer 30 plays a role of a liquid passage toward either the evaporation section or the condenser section and the evaporator section depending on the position of the heat source 100. In addition, the sparse mesh 21 or the sparse mesh layer 20 plays a role of not only a vapor passage but also a returning route through which the working fluid returns to the condenser section and the working fluid condensed in the condenser section returns to the dense mesh layer 30 which is the evaporator section. According to the present invention, since the sparse mesh acts as the vapor passage, a separate room for making a vapor passage is not necessary. In addition, since the mesh is interposed between the upper and lower plates of the case to support them, the case is not distorted even in the vacuum process for filling the working fluid.

According to the present invention, the sparse mesh and the dense mesh may be provided in various shapes, as shown in FIGS. 11 to 17. In the drawings, the same component is endowed with the same reference numeral.

FIG. 11 shows a heat transfer device according to another preferred embodiment of the present invention. Referring to FIG. 11, in the heat transfer device, dense mesh layers 30a and 30b are formed between the upper and lower plates 11 and 12, and the sparse mesh layer 20 acting as a vapor passage is interposed between the dense mesh layers 30a and 30b. In the drawing, the dense mesh layers 30a and 30b respectively has at least one dense mesh, just expressed by hatching. In addition, the sparse mesh layer 20 has at least one sparse mesh, just expressed by dots.

For example, in case the lower plate 12 is contacted with heat source (not shown) and the heat dissipating unit (not shown) is provided on the upper plate 11, the working fluid evaporated from the lower dense mesh layer 30a is diffused to all directions through the vapor passages of the sparse mesh layer 20, and then preferably emits heat at the upper dense mesh layer 30b contacted with the upper plate 11 and is then condensed into a liquid state. Since the mesh number (N) of the dense mesh is relatively greater than the sparse mesh, the dense mesh has more condensing points at which the vapor may be condensed, thereby improving the heat emitting efficiency. In addition, the upper dense mesh layer 30b provides a returning passage so that the condensed working fluid may flow to the lower dense mesh layer 30a through the sparse mesh layer 20.

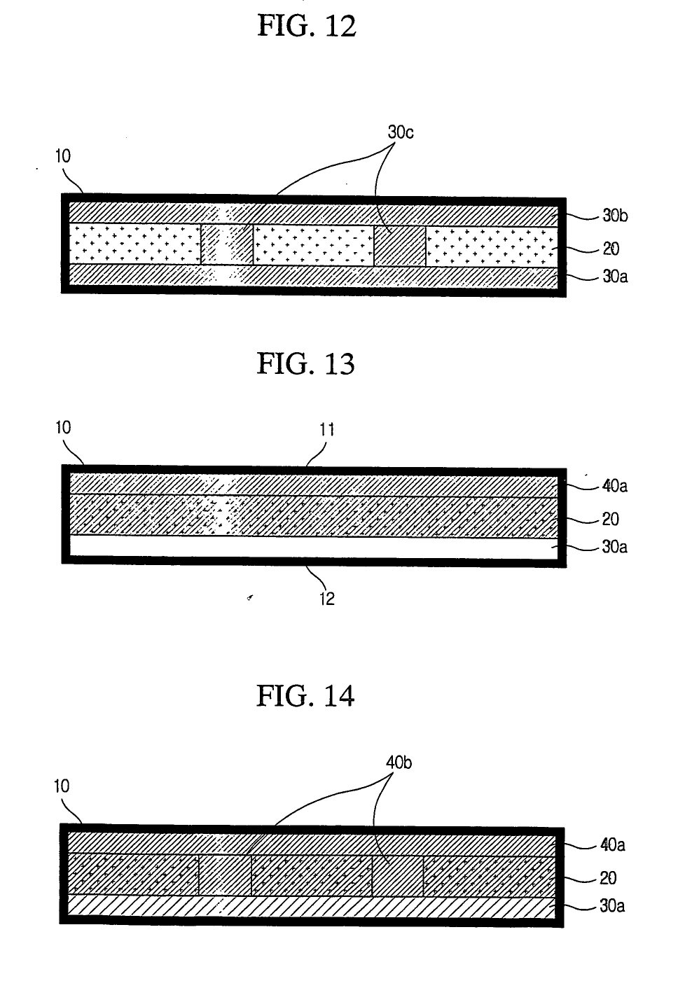

FIG. 12 shows a heat transfer device according to still another embodiment of the present invention. Referring to FIG. 12, there is additionally provided at least one layer of dense mesh 30c at a partial region of the sparse mesh layer 20 between the dense mesh layers 30a and 30b for giving a liquid passage by interconnecting the dense mesh layers 30a and 30b. Thus, the working fluid emitting heat at the heat dissipating unit and condensed in the upper dense mesh layer 30b may easily move to the lower dense mesh layer 30a.

According to the present invention, it is also possible to provide more than three kinds of mesh layers having different mesh numbers, as shown in FIG. 13 as an example. In the heat transfer device of FIG. 13, a dense mesh layer 30a made of at least one layer of dense mesh is provided on the inner surface of the lower plate 12 of the case 10 adjacent to the heat source (not shown) in order to transfer heat to the working fluid to evaporate, and a sparse mesh layer 20 made of at least one layer of sparse mesh is provided over the dense mesh layer 30a in order to give a passage for the evaporated working fluid. In addition, a middle mesh layer 40a made of at least one layer of middle mesh having the mesh number relatively greater than the sparse mesh and relatively smaller than the dense mesh is provided on the inner surface of the upper plate 11 of the case at which the heat dissipating unit (not shown) is positioned. Here, the middle mesh layer 40a improves the condensed heat transferring of the vapor further.

Moreover, as shown in FIG. 14, at least one layer of middle mesh layer 40b may be further provided to at least a partial region of the sparse mesh layer 20 between the middle mesh layer 40a and the dense mesh layer 30a for connecting the middle mesh layer 40a to the dense mesh layer 30a in order to provide a liquid passage for the working fluid condensed in the middle mesh layer 40a toward the dense mesh layer 30a. Though not shown in the figure, the middle mesh layer 40b can be substituted with a dense mesh layer.

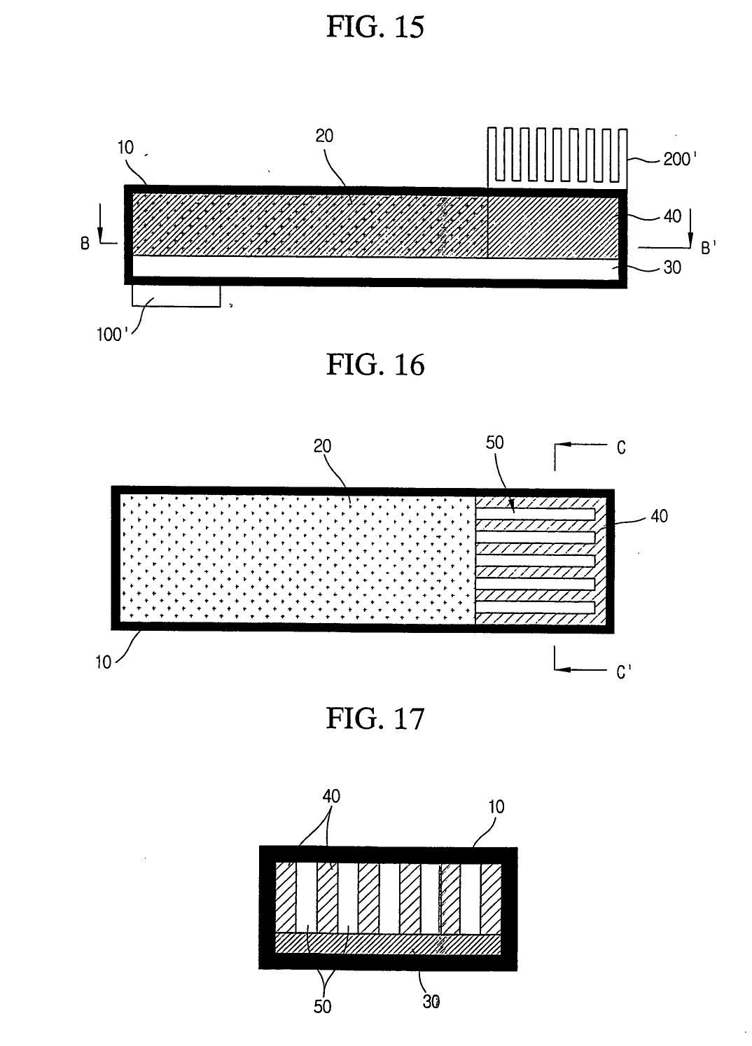

FIGS. 15 to 17 show configuration of a flat plate heat transfer device according to another embodiment of the present invention. FIG. 16 is a plane sectional view taken along a B-B′ line of the heat transfer device shown in FIG. 15, and FIG. 17 is a side sectional view taken along a C-C′ line of FIG. 16. This embodiment is particularly suitable for a heat pipe.

Referring to figures, the dense mesh layer 30 is provided in the case 10 at a position adjacent to a heat source 100′, and the middle mesh layer 40 is provided near a heat dissipating unit 200′ at which the working fluid emits heat and is condensed. In addition, the dense mesh layer 30 and the middle mesh layer 40 are connected by a sparse mesh layer 20. Here, the dense mesh layer 30 acts as an evaporator section of the working fluid, the sparse mesh layer 20 acts as a vapor passage, and the middle mesh layer 40 acts as a condenser section of the working fluid. Thus, a working fluid is evaporated by the heat transferred from the heat source 100′ to the dense mesh layer 30, and the vapor working fluid flows through the vapor passage of the sparse mesh layer 20 to the middle mesh layer 40. Subsequently, at the middle mesh layer 40, the vapor emits heat to the heat dissipating unit 200′ and then condenses. The condensed working fluid in a liquid state is then returned to the evaporator section through the dense mesh layer 30 by means of the capillary force.

According to this embodiment, in order to promote the condensation heat transferring and prevent from blocking of vapor passage due to the liquid-blanket formation, a vapor flowing space 50 (see FIGS. 16 and 17) is preferably formed in the middle mesh layer 40 so that the vapor flowed from the sparse mesh layer 20 may flow therethrough. In this case, the vapor passing through the sparse mesh layer 20 may diffuse more easily to every place of the middle mesh layer 40, thereby improving condensation efficiency and heat emitting efficiency.

As an alternative, the middle mesh layer 40 may be replaced with a dense mesh layer. In this case, a vapor flowing space may be formed in the above dense mesh layer, identically to the above case. Furthermore, the vapor flowing space is not limited to this embodiment, but the vapor flowing space may be suitably designed in the case of other embodiments so that it may be communicated with the sparse mesh to guide the working fluid passing through the vapor passage of the sparse mesh to the condenser section or the heat emitting portion.

Experiments

The upper and lower plates having a thickness of 70 μm made of an electrolytic copper foil is used to fabricate a case that has a coarse surface having the wick structure inside. The case has a length of 80 mm, a width of 60 mm, and a height of 0.78 mm. The case includes a copper mesh containing over 99 wt % copper. This copper mesh is composed of one layer of sparse mesh and one layer of dense mesh. The sparse mesh has a wire diameter (d) of 0.225 mm, a thickness of 0.41 mm, the mesh number (N) of 15, while the dense mesh has a wire diameter (d) of 0.11 mm, a thickness of 0.22 mm, and the mesh number (N) of 100. The upper and lower plates of the case are sealed using a denaturalized acrylic binary bond (HARDLOC C-323-03A and C-323-03B) manufactured by DENKA in Japan. Before charging a working fluid into the case, a vacuum pump is used to make the inside of the case into a vacuum up to 1.0×10⁻⁷ torr. After that, a distilled water of 2.3 cc is filled in the case and then the case is sealed.

As a comparative example for comparison with the experimental example of the present invention, a copper test piece having a size identical to the above case is prepared.

The case and the copper test piece are installed so that an upper surface is in contact with a lower portion of a fin heat sink to which a cooling fan is mounted. At a lower surface of the case and the copper test piece, a heat source of which length and width are respectively 20 mm is attached, respectively. And then, with increasing a caloric power of the heat source to 30 W, 40 W and 50 W at an identical air condition and a constant fan speed, the temperature of the heat source surface and the temperature of the lower surface of the fin heat sink are measured, and a thermal resistance between the heat source surface and the ambient is also obtained. In addition, the same measurement is conducted after attaching the heat source directly to the lower surface of the fin heat sink without attaching the flat plate heat transfer device or the copper test piece. The results of the experiments are well shown in the following table 1.

TABLE 1

| Caloric power [W] | | 30 | 40 | 50 |
|---|---|---|---|---|
| None attached | Temperature of Heat | 75.22 | 85.77 | 96.52 |
| | Source [° C.] | | | |
| | Thermal Resistance | 2.42 | 1.506 | 1.409 |
| | [° C./W] | | | |
| Copper (OFHC) | Temperature of Heat | 63.43 | 74.79 | 86.21 |
| | Source [° C.] | | | |
| | Thermal Resistance | 1.204 | 1.181 | 1.168 |
| | [° C./W] | | | |
| Present Invention | Temperature of Heat | 53.73 | 59.99 | 65.29 |
| | Source [° C.] | | | |
| | Thermal Resistance | 0.83 | 0.77 | 0.74 |
| | [° C./W] | | | |

As well understood from the above table, the thermal resistance of the flat plate heat transfer device according to the present invention is 1.9 times than the conventional one, and 1.5 times than the copper. Particularly, the temperature of the heat source is over 20° C. lower than the conventional one, and over 10° C. lower than the copper. As described above, owing to the excellent heat transferring ability, the flat plate heat transfer device of the present invention may be applied for cooling various electronic equipments.

### INDUSTRIAL APPLICABILITY

The heat transfer device according to the present invention may be realized in various shapes of flat plate with a thin thickness by use of a mesh providing a vapor passage. In particular, the flat plate heat transfer device of the present invention may be manufactured at a very low price by the use of cheap mesh and case without the MEMS process or the etching process which require a lot of costs. Furthermore, the mesh provided in the heat transfer device prevents distortion or crush of the case during or after the vacuum treatment in the manufacturing process, so the reliability of the product can be improved. Such a flat plate heat transfer device of the present invention can be efficiently used for cooling various electronic equipments including a portable electronic equipment.

The present invention has been described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

1. A flat plate heat transfer device comprising:
a thermally-conductive flat plate case installed between a heat source and a heat dissipating unit for containing a working fluid which evaporates by absorbing heat from the heat source and condenses by emitting heat at the heat dissipating unit; and
at least one layer of mesh installed in the case and having wires woven alternately,
wherein a vapor passage is formed along the surface of the wires from junctions of the mesh so that the evaporated working fluid is capable of flowing therethrough.

2. The flat plate heat transfer device according to claim 1, wherein an opening spacing of the mesh [M=(1−Nd)/N] ranges between 0.19 mm and 2.0 mm,
where N is the mesh number, and d is a diameter (inch) of the wire.

3. The flat plate heat transfer device according to claim 1, wherein a diameter of the mesh wire ranges between 0.17 mm and 0.5 mm.

4. The flat plate heat transfer device according to claim 1, wherein an opening area of the mesh ranges between 0.036 mm² and 4.0 mm².

5. The flat plate heat transfer device according to claim 1, wherein the mesh number is not more than 60 on the basis of ASTM specification E-11-95.

6. The flat plate heat transfer device according to claim 1, wherein the mesh includes: at least one layer of sparse mesh for providing a vapor passage for the evaporated working fluid; and at least one layer of dense mesh having a mesh number relatively greater than that of the sparse mesh and providing a liquid passage for the working fluid.

7. The flat plate heat transfer device according to claim 6, wherein an opening spacing of the dense mesh [M=(1−Nd)/N] ranges between 0.019 mm and 0.18 mm, where N is the mesh number, and d is a diameter (inch) of the wire.

8. The flat plate heat transfer device according to claim 6, wherein a diameter of the dense mesh wire ranges between 0.02 mm and 0.16 mm.

9. The flat plate heat transfer device according to claim 6, wherein an opening area of the dense mesh ranges between 0.00036 mm² and 0.0324 mm².

10. The flat plate heat transfer device according to claim 6, wherein the number of the sparse mesh is not more than 60 on the basis of ASTM specification E-11-95, while the number of the dense mesh is not more than 80 on the basis of ASTM specification E-11-95.

11. The flat plate heat transfer device according to claim 6, wherein the dense mesh is arranged near the heat source, while the sparse mesh positioned on the dense mesh is arranged near the heat dissipating unit.

12. The flat plate heat transfer device according to claim 6, wherein the sparse mesh is interposed between the dense mesh layers.

13. The flat plate heat transfer device according to claim 12, further comprising at least one layer of additional dense mesh for connecting the dense meshes to at least a part of the sparse mesh between the dense meshes in order to provide a liquid passage for a working fluid.

14. The flat plate heat transfer device according to claim 6, further comprising at least one layer of middle mesh having the mesh number relatively greater than the sparse mesh and relatively smaller than the dense mesh.

15. The flat plate heat transfer device according to claim 14, wherein the sparse mesh is interposed between the dense mesh and the middle mesh.

16. The flat plate heat transfer device according to claim 15, further comprising at least one layer of additional dense mesh for connecting the dense mesh layer and the middle mesh layer to at least a part of the sparse mesh between the dense mesh and the middle mesh in order to provide a passage.

17. The flat plate heat transfer device according to claim 15, further comprising at least one layer of additional middle mesh for connecting the dense mesh layer and the middle mesh layer to at least a part of the sparse mesh between the dense mesh and the middle mesh in order to provide a passage.

18. The flat plate heat transfer device according to claim 15, wherein the dense mesh is arranged near the heat source, while the middle mesh is arranged near the heat dissipating unit.

19. The flat plate heat transfer device according to claim 14, wherein the dense mesh is arranged near the heat source so that the working fluid is evaporated into a vapor by the heat absorbed from the heat source, wherein the sparse mesh is arranged in contact with the dense mesh in order to provide a vapor passage through which the evaporated working fluid flows, and wherein the middle mesh is arranged near the heat dissipating unit and in contact with the sparse mesh in order to emit heat to the heat dissipating unit so that the vapor is condensed.

20. The flat plate heat transfer device according to claim 19, wherein the middle mesh has a vapor flowing space so that the vapor from the sparse mesh flows therein.

21. The flat plate heat transfer device according to claim 1, further comprising a wick structure installed in the flat plate case in contact with the mesh,
wherein the wick structure has protrusions on a surface thereof so that the working fluid flows in the wick structure and the working fluid is evaporated using the heat absorbed from the heat source and then transferred to the mesh.

22. The flat plate heat transfer device according to claim 21, wherein the wick structure is formed by sintered copper, stainless steel, aluminum or nickel powder.

23. The flat plate heat transfer device according to claim 21, wherein the wick structure is formed by etching polymer, silicon, silica, copper plate, stainless steel, nickel or aluminum plate.

24. The flat plate heat transfer device according to claim 1, wherein the flat plate case is made using an electrolytic copper film so that a coarse surface becomes an inner side of the case.

25. The flat plate heat transfer device according to claims 1, wherein the mesh is made of one selected from the group consisting of metal, polymer and plastic.

26. The flat plate heat transfer device according to claim 25, wherein the metal is selected from the group consisting of copper, aluminum, stainless steel, molybdenum and their alloys.

27. The flat plate heat transfer device according to claim 1, wherein the flat plate case is made of one selected from the group consisting of metal, polymer and plastic.

28. The flat plate heat transfer device according to claim 27, wherein the metal is selected from the group consisting of copper, aluminum, stainless steel, molybdenum and their alloys.

29. The flat plate heat transfer device according to claims 1, wherein the working fluid is selected from the group consisting of water, ethanol, ammonia, methanol, nitrogen and Freon.

30. The flat plate heat transfer device according to claim 29, wherein the amount of the working fluid filled in the case is 20-80% of the inner volume of the case.

31. A method for making a flat plate heat transfer device comprising the steps of:
forming upper and lower plates of a thermally-conductive flat plate case respectively;
inserting at least one layer of mesh into the case, the mesh having wires woven alternately in order to form a vapor passage through which an evaporated vapor is capable of flowing along the surface of the wires from junctions of the mesh;
making a case by uniting the upper and lower plates;
charging the working fluid into the united case in a vacuum state; and
sealing the case to which the working fluid is charged.

32. A method for making a flat plate heat transfer device comprising the steps of:
forming upper and lower plates of a thermally-conductive flat plate case respectively;
inserting at least one layer of sparse mesh and at least one layer of dense mesh in the case, the sparse mesh having wires woven alternately and forming a vapor passage through which an evaporated working fluid is capable of flowing along the surface of the wires to junction of the mesh, the dense mesh having the mesh number relatively greater than the sparse mesh and providing a liquid passage for the working fluid;
making a case by uniting the upper and lower plates;
charging the working fluid into the united case in a vacuum state; and
sealing the case to which the working fluid is charged.

33. The method for making a flat plate heat transfer device according to claim 31 or 32, wherein the upper and lower plates are united using one selected from the group consisting of brazing, TIG welding, soldering, laser welding, electron beam welding, friction welding, bonding and ultrasonic welding.
